(19) United States
(12) Patent Application Publication
(10) Pub. No.: US 2026/0101722 A1
(43) Pub. Date: Apr. 9, 2026

(54) SUBSTRATE, METHOD OF INSPECTING THE SUBSTRATE, AND ELECTRONIC DEVICE INCLUDING THE SUBSTRATE

(71) Applicant: Samsung Display Co., LTD., Yongin-si (KR)

(72) Inventor: HYUNGJIN LEE, Yongin-si (KR)

(21) Appl. No.: 19/237,940

(22) Filed: Jun. 13, 2025

(30) Foreign Application Priority Data
Oct. 8, 2024 (KR) 10-2024-0136890

(51) Int. Cl. H01L 21/66; H01L 23/544

(52) U.S. Cl. CPC H10P 74/203; H10W 46/00; H10W 46/301

(57) ABSTRACT

A method of inspecting the substrate according to an embodiment of the present disclosure may include placing a substrate including a plurality of cells, a first alignment key, and a second alignment key spaced apart from the first alignment key in a plan view on a stage, performing a first correcting which corrects misalignment of a first camera using the first alignment key, obtaining a first image by capturing an image of the substrate with the first camera, detecting a foreign substance in the first image, moving the stage such that the substrate overlaps a second camera in a plan view, performing a second correcting which corrects misalignment of the second camera using the second alignment key, and obtaining a second image by capturing, with the second camera, an image of a cell among the cells in which the foreign substance is detected.

This application claims priority to Korean Patent Application No. 10-2024-0136890, filed on Oct. 8, 2024, and all the benefits accruing therefrom under 35 U.S.C. § 119, the content of which in its entirety is herein incorporated by reference.

### BACKGROUND

### 1. Field

The present disclosure relates to a substrate, a method of inspecting the substrate, and electronic device including the substrate. More specifically, the present disclosure relates to the substrate that provides visual information, the method of inspecting the substrate, and the electronic device including the substrate.

### 2. Description of the Related Art

With an advancement of technology, display products are becoming smaller, lighter, and more efficient while achieving superior performance. In particular, high-resolution display devices, such as, for example, plasma display devices, liquid crystal display devices, and organic light-emitting display devices, are gaining attention.

In the manufacturing of display panels included in such display devices, an optical inspection device may be used to detect defects in the display panel. However, depending on the inspection conditions, a captured image may be distorted or misaligned, leading to reduced inspection accuracy. To address this issue, various efforts are continuously being made to enhance inspection accuracy.

### SUMMARY

One purpose of the present disclosure is to provide a method of inspecting a substrate with improved reliability.

Another purpose of the present disclosure is to provide the substrate used in the method of inspecting the substrate.

Still another purpose of the present disclosure is to provide an electronic device including the substrate.

A method of inspecting a substrate according to an embodiment of the present disclosure includes placing a substrate including a plurality of cells, a first alignment key, and a second alignment key spaced apart from the first alignment key in a plan view on a stage, performing a first correcting which corrects misalignment of a first camera using the first alignment key, obtaining a first image by capturing an image of the substrate with the first camera, detecting a foreign substance in the first image, moving the stage such that the substrate overlaps a second camera in a plan view, performing a second correcting which corrects misalignment of the second camera using the second alignment key, and obtaining a second image by capturing, with the second camera, an image of a cell among the plurality of cells in which the foreign substance is detected.

In an embodiment, the substrate may include a first area and a second area adjacent to the first area, and the first alignment key includes a first-first alignment key disposed in the first area and a first-second alignment key disposed in the second area.

In an embodiment, in capturing the substrate with the first camera, the first camera may include a first-first camera and a first-second camera, capturing the substrate with the first camera may include: capturing the first area using the first-first camera, and capturing the second area using the first-second camera.

In an embodiment, capturing the image of the substrate with the first camera may be in a line scan manner.

In an embodiment, the substrate may further include third alignment keys corresponding one-to-one with the plurality of cells.

In an embodiment, each of the third alignment keys may be disposed at a center of one side of a corresponding cell among the plurality of cells.

In an embodiment, each of the first alignment key, the second alignment key, and the third alignment keys may have a cross shape in the plan view.

In an embodiment, the method may further include, before obtaining the second image by capturing with the second camera, performing a third correcting which corrects a misalignment of the second camera using a third alignment key included among the third alignment keys, wherein the third alignment key corresponds to a cell in which the foreign substance is detected among the plurality of cells

In an embodiment, the third correcting may be performed using a pre-stored first grayscale of the third alignment key and a second grayscale of the third alignment key determined based on an image of the third alignment key as captured by the second camera.

In an embodiment, the third correcting may be performed using Formula 1.

$$Normalized Gray Scale ( f , g ) = \frac{( f ( x , y ) − \overline{f} ) ( g ( x , y ) − \overline{g} )}{\sum f ( x , y ) g ( x , y )}$$

wherein, f(x, y) is the second grayscale of the third alignment keys for each area, and f̅ is an average value of f(x, y),
g(x, y) is the pre-stored first grayscale of the third alignment keys for each area, and g is an average value of g(x, y).

In an embodiment, the third correcting may be performed until a value of the Normalized Gray Scale(f, g) is equal to or more than about 0.85.

In an embodiment, detecting the foreign substance in the first image may include: matching the first image of each of the cells with each other, and determining that areas with a grayscale value difference greater than a preset threshold includes a foreign substance.

In an embodiment, matching each first image of the cells may include using the third alignment keys for matching.

In an embodiment, the first correcting may include verifying whether the first alignment key is positioned at a center of a screen of the first camera.

In an embodiment, the second correcting may include verifying whether the second alignment key is positioned at a center of a screen of the second camera.

In an embodiment, a resolution of the second camera may be higher than a resolution of the first camera.

A substrate according to an embodiment of the present disclosure includes a cell area in which a plurality of cells is disposed and a peripheral area surrounding at least a portion of the cell area, a first alignment key disposed in the peripheral area, a second alignment key disposed in the peripheral area and spaced apart from the first alignment key in a plan view, and third alignment keys disposed in the cell area, corresponding one-to-one with the plurality of cells, wherein each of the third alignment keys is disposed on one side of a corresponding cell among the plurality of cells.

In an embodiment, the substrate may include a first area and a second area adjacent to the first area, and the first alignment key may include a first-first alignment key disposed in the first area and a first-second alignment key disposed in the second area.

In an embodiment, each of the first alignment key, the second alignment key, and the third alignment keys may have a cross shape in the plan view.

An electronic device according to an embodiment of the present disclosure includes a display device and a processor configured to drive the display device, wherein the display device is inspected by a method of inspecting a substrate including placing a substrate including a plurality of cells, a first alignment key, and a second alignment key spaced apart from the first alignment key in a plan view on a stage, performing a first correcting which corrects misalignment of a first camera using the first alignment key, obtaining a first image by capturing an image of the substrate with the first camera, detecting a foreign substance in the first image, moving the stage such that the substrate overlaps a second camera in a plan view, performing a second correcting which corrects misalignment of the second camera using the second alignment key, and obtaining a second image by capturing, with the second camera, an image of a cell among the plurality of cells in which the foreign substance is detected.

Accordingly, even when the substrate is enlarged (e.g., enlarged than a predetermined size), a distortion of the first camera and the second camera may be corrected through the first, second, and third correcting. Accordingly, a location of the foreign substance may be accurately specified, and the coordinates of the foreign substance captured by the first camera may be magnified by the second camera and accurately determined. As a result, the techniques described herein support accurately determining locations of foreign substances and overcoming problems in a manufacturing process of the substrate by analyzing the foreign substances through the first camera and the second camera.

### BRIEF DESCRIPTION OF THE DRAWINGS

The accompanying drawings, which are included to provide a further understanding of the inventive concept and are incorporated in and constitute a part of this specification, illustrate embodiments of the inventive concept together with the description.

FIG. 1 is a cross-sectional view illustrating a first camera according to an embodiment of the disclosure.

FIG. 2 is a plan view illustrating an embodiment of the substrate of FIG. 1.

FIG. 3 is a perspective view illustrating the first camera and the first alignment key of FIG. 1.

FIGS. 4 and 5 are plan views illustrating a first correcting of the first camera of FIG. 3.

FIG. 6 is a plan view illustrating a first image captured of the substrate of FIG. 2.

FIG. 7 is a perspective view illustrating the second camera and the second alignment key.

FIGS. 8 and 9 are plan views illustrating a second correcting of the second camera of FIG. 7.

FIGS. 10, 11, and 12 are views illustrating a third correcting of the second camera of FIG. 10.

FIG. 13 is a flow-chart illustrating a method of inspecting the substrate according to an embodiment of the disclosure.

FIG. 14 is a flow-chart illustrating a step of detecting a foreign substance of FIG. 13.

FIG. 15 is a block-diagram illustrating an electronic device according to an embodiment of the present disclosure.

FIG. 16 is a schematic diagram of the electronic device according to various embodiments of FIG. 15.

### DETAILED DESCRIPTION

Regarding embodiments of the present disclosure disclosed in this text, specific structural and functional descriptions are illustrative for a purpose of explaining the embodiments of the present disclosure, and the embodiments of the present disclosure may be implemented in various forms and should not be construed as limited to the embodiments described in.

Since the present disclosure may be subject to various changes and may have various forms, specific embodiments will be illustrated in the drawings and described in detail in the text. However, this is not intended to limit the present disclosure to a specific disclosed form, and should be understood to include all changes, equivalents, and substitutes included in the spirit and technical scope of the present disclosure.

Terms such as first, second, and the like may be used to describe various components, but the components should not be limited by the terms. The above terms may be used for a purpose of distinguishing one component from another component. For example, a first component may be referred to as a second component, and similarly, the second component may be referred to as a first component without departing from the scope of the present disclosure.

It will be understood that when an element is referred to as being “connected” or “coupled” to another element, it may be directly connected or coupled to the other element or intervening element(s) may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” and the like).

The terminology used herein is for a purpose of describing particular example embodiments and is not intended to be limiting of the embodiments of the present disclosure. As used herein, the singular forms “a,” “an” and “the” are intended to include plural forms as well, unless the context clearly indicates otherwise. It will be further understood that the terms “comprises” and/or “comprising,” when used in this specification, specify a presence of stated features, integers, steps, operations, elements, and/or components, but do not preclude the presence or addition of one or more other features, integers, steps, operations, elements, components, and/or groups thereof.

Terms such as “below”, “at the bottom”, “lower”, “below”, “above”, “on top”, “on the top”, “on”, and the like are used to explain a relationship between components illustrated in the drawings. The terms are relative concepts and are explained based on the direction indicated in the drawings.

The terms “about” or “approximately” as used herein are inclusive of the stated value and include a suitable range of deviation for the particular value as determined by one of ordinary skill in the art, considering the measurement in question and the error associated with measurement of the particular quantity. The terms “about” or “approximately” can mean within one or more standard deviations, or within +30%, 20%, 10%, 5% of the stated value, for example.

The term “substantially,” as used herein, means approximately or actually. The term “substantially equal” means approximately or actually equal. The term “substantially the same” means approximately or actually the same. The term “substantially perpendicular” means approximately or actually perpendicular. The term “substantially parallel” means approximately or actually parallel.

Unless otherwise defined, all terms (including technical and scientific terms) used herein have a same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments will be described in detail with reference to the accompanying drawings. Same reference numerals are used for same components in the drawings, and redundant descriptions of same components will be omitted.

In this specification, a plane may be defined by a first direction D1 and a second direction D2 that intersects the first direction D1. For example, the second direction D2 may be perpendicular to the first direction D1. In some aspects, a third direction D3 may be a normal direction of the plane. That is, the third direction D3 may be perpendicular to the plane formed by the first direction D1 and the second direction D2.

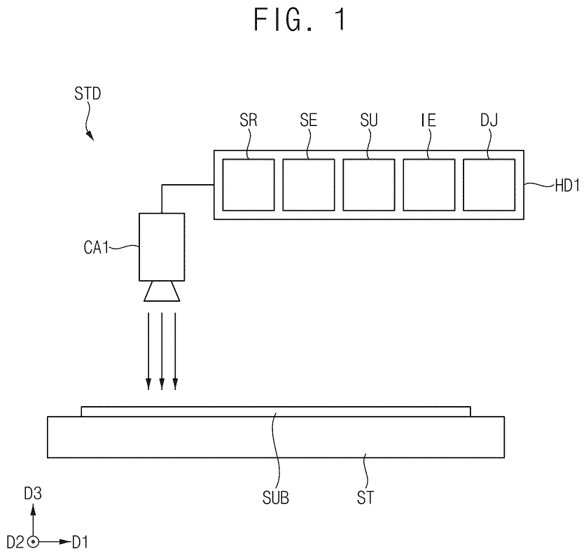

FIG. 1 is a cross-sectional view illustrating a first camera according to an embodiment of the disclosure.

Referring to FIG. 1, an inspection device STD may include a stage ST, a first camera CA1, and a first processor HD1. The first processor HD1 may include a storage portion SR, a gradation extraction portion SE, an alignment portion SU, an image extraction portion IE, and a defect determination portion DJ.

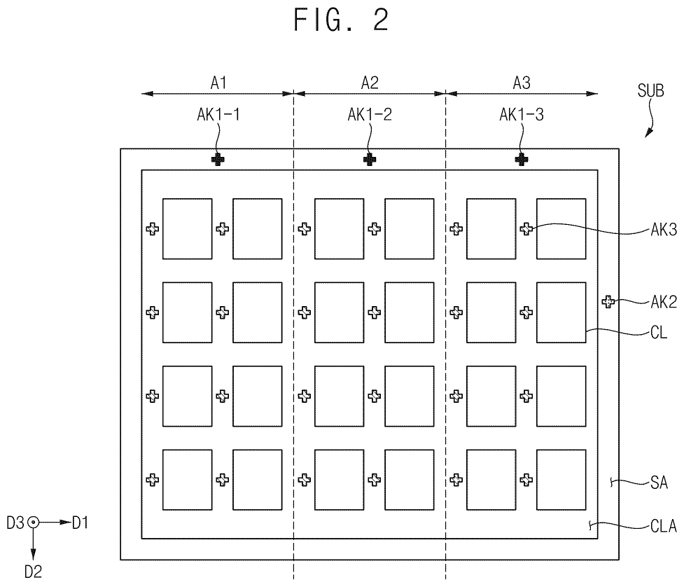

A substrate SUB, which is an inspection target for determining defect occurrence using the inspection device STD, may be disposed on the stage ST. For example, the substrate SUB may be a substrate of a display device including a plurality of cells (e.g., cells CL in FIG. 2).

The first camera CA1 may capture an image of the substrate SUB disposed on the stage ST. Accordingly, the first camera CA1 may obtain a captured image of the substrate SUB.

In an embodiment, the first camera CA1 may be a charge-coupled device (CCD) camera. That is, the first camera CA1 may be a device that captures an image of the substrate SUB using light. The first camera CA1 may capture an image of the substrate SUB in one direction. For example, the first camera CA1 may irradiate light while moving in a first direction D1 onto the substrate SUB and capture a reflected image.

The storage portion SR may store the captured image obtained by the first camera CA1.

The gradation extraction portion SE may obtain a gradation value of the captured image. For example, the gradation extraction portion SE may generate gradation values by converting the captured image obtained by the first camera CA1 into grayscale. In an embodiment, the gradation extraction portion SE may analyze the captured image and generate gradation values ranging from 0 to 255.

The alignment portion SU may align the captured image. In an embodiment, the captured image may be obtained by capturing an image of the substrate SUB with the first camera CA1 while changing a relative position of the first camera CA1 to the substrate SUB. In this case, for example, alignment errors may occur in the captured image due to errors in a movement device that moves the first camera CA1 or the stage ST. The alignment portion SU may correct alignment errors in the captured image.

The image extraction portion IE may extract an inspection target image and at least one comparison image matching the inspection target image from the captured image.

The defect determination portion DJ may determine whether a defect has occurred in the captured image. For example, the defect determination portion DJ may compare the inspection target image extracted by the image extraction portion IE with the comparison image to determine whether a defect is present in an area where the inspection target image was captured. However, the embodiments of the disclosure are not necessarily limited thereto. The defect determination portion DJ may also determine defects based on the gradation analyzed by the gradation extraction portion SE.

FIG. 2 is a plan view illustrating an embodiment of the substrate of FIG. 1.

Referring to FIGS. 1 and 2, the substrate SUB may include a cell area CLA where multiple cells CL are disposed and a peripheral area SA that surrounds at least a portion of the cell area CLA. In FIG. 2, the substrate SUB is illustrated as having a rectangular shape in a plan view, however embodiments of the disclosure are not necessarily limited thereto. A plane shape of the substrate SUB may include various forms such as, for example, circular, elliptical, or polygonal shapes.

In the cell area CLA of the substrate SUB, the multiple cells CL may be disposed. The cells CL may be disposed in a matrix form along the first direction D1 and/or the second direction D2. The cells CL may be unit substrates included in display devices (e.g., smartphones, tablets, or the like). In FIG. 2, each of the cell CL is illustrated as having a rectangular shape in a plan view, however embodiments of the disclosure are not necessarily limited thereto. The cells CL may have various plane shapes, such as, for example, circular, elliptical, or polygonal shapes.

In an embodiment, the substrate SUB may define a first area A1, a second area A2, and a third area A3. The first area A1, the second area A2, and the third area A3 may be defined along the first direction D1. Specifically, the second area A2 may be adjacent to the first area A1 in the first direction D1, and the third area A3 may be adjacent to the second area A2 in the first direction D1.

In an embodiment, the substrate SUB may include a first alignment key AK1. The first alignment key AK1 may include a first-first alignment key AK1-1, a first-second alignment key AK1-2, and a first-third alignment key AK1-3. The first alignment key AK1 may be disposed on one side of the peripheral area SA of the substrate SUB. In FIG. 2, the first alignment key AK1 is illustrated as including three alignment keys, however embodiments of the disclosure are not necessarily limited thereto. The first alignment key AK1 may include two or less, or four or more alignment keys.

For example, the first alignment key AK1 may be disposed in the first, second, and third areas A1, A2, and A3 of the substrate SUB. Specifically, the first-first alignment key AK1-1 may be disposed in the first area A1 of the substrate SUB. The first-second alignment key AK1-2 may be disposed in the second area A2 of the substrate SUB. The first-third alignment key AK1-3 may be disposed in the third area A3 of the substrate SUB.

A second alignment key AK2 may be further disposed in the peripheral area SA of the substrate SUB. The second alignment key AK2 may be spaced apart from the first alignment key AK1 in a plan view. For example, as illustrated in FIG. 2, the second alignment key AK2 may be disposed at an area rotated clockwise from the first alignment key AK1. However, the embodiments of the disclosure are not necessarily limited thereto.

Multiple third alignment keys AK3 may be disposed in the cell area CLA of the substrate SUB. The third alignment keys AK3 may be disposed in a matrix form along the first direction D1 and/or the second direction D2. The third alignment keys AK3 may be disposed in a one-to-one correspondence with the cells CL. For example, each of the third alignment keys AK3 may be disposed on one side of each of the cells CL.

In an embodiment, as illustrated in FIG. 2, the first alignment key AK1, the second alignment key AK2, and the third alignment keys AK3 may have a cross shape in a plan view. However, the embodiments of the disclosure are not necessarily limited thereto. The first alignment key AK1, the second alignment key AK2, and the third alignment keys AK3 may have various shapes in a plan view, such as, for example, triangular, rectangular, or elliptical shapes.

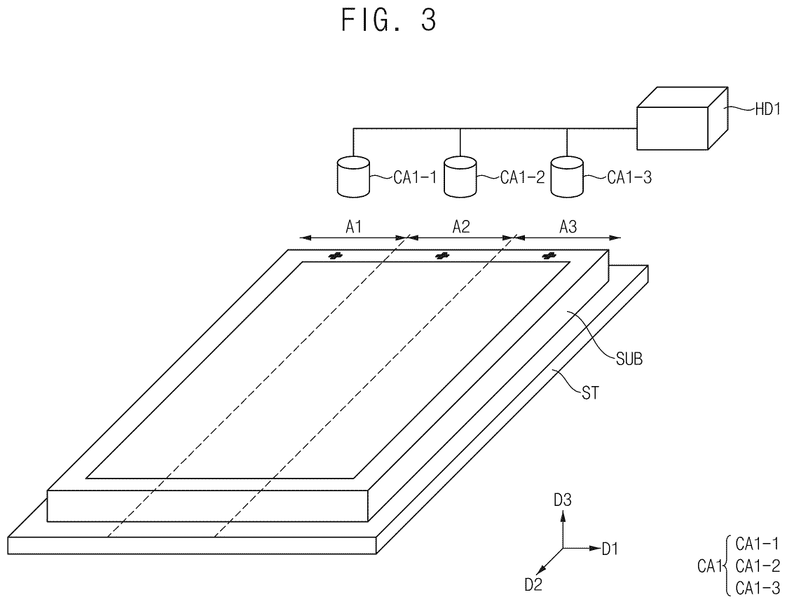

FIG. 3 is a perspective view illustrating the first camera and the first alignment key of FIG. 1.

Referring to FIGS. 1, 2, and 3, the first camera CA1 may include a first-first camera CA1-1, a first-second camera CA1-2, and a first-third camera CA1-3. However, the embodiments of the disclosure are not necessarily limited thereto. The first camera CA1 may include two or less, or four or more cameras.

In an embodiment, the first-first camera CA1-1, the first-second camera CA1-2, and the first-third camera CA1-3 may correspond one-to-one with the first, second, and third areas A1, A2, and A3 of the substrate SUB. As the substrate SUB is defined into three areas along the first direction D1, the first camera CA1 may include three cameras to capture an image(s) of each area. That is, if the substrate SUB is defined into four or more areas along the first direction D1, the first camera CA1 may also include four or more cameras.

In an embodiment, the first camera CA1 may capture an image of an entire surface of the substrate SUB. Specifically, the first camera CA1 may capture an image(s) of the cells CL disposed in the cell area CLA of the substrate SUB. For example, the first camera CA1 may capture an image(s) of the substrate SUB in a line scan manner along the second direction D2. That is, the first camera CA1 may move along the second direction D2 while capturing an image(s) of the substrate SUB. However, the embodiments of the disclosure are not necessarily limited thereto.

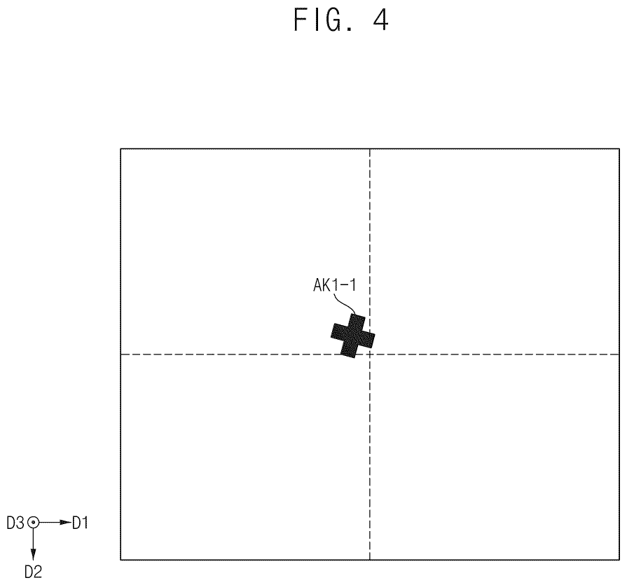

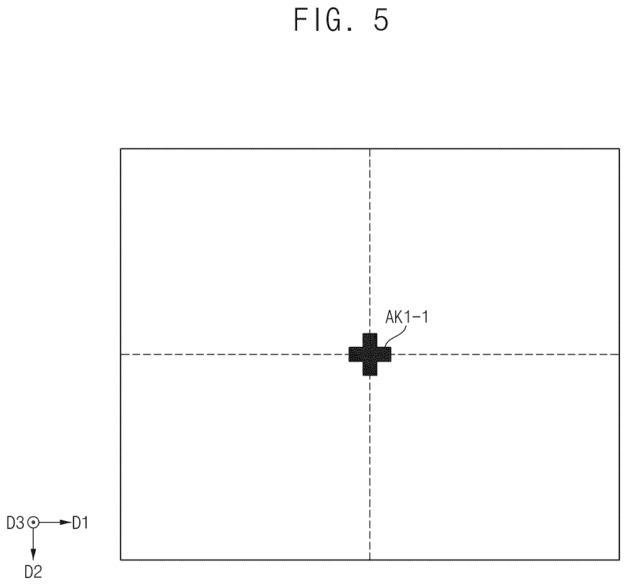

FIGS. 4 and 5 are plan views illustrating a first correcting of the first camera of FIG. 3. Specifically, FIGS. 4 and 5 may illustrate a screen (e.g., something that a user views displayed by the camera) where the first-first camera CA1-1 captures the first-first alignment key AK1-1.

Although FIGS. 4 and 5 describe the first-first camera CA1-1 and the first-first alignment key AK1-1 as central elements, the first-second camera CA1-2 and the first-second alignment key AK1-2, as well as the first-third camera CA1-3 and the first-third alignment key AK1-3, may perform substantially the same function as the first-first camera CA1-1 and the first-first alignment key AK1-1. Therefore, overlapping details may be omitted or summarized.

Referring to FIGS. 3, 4, and 5, before the first camera CA1 captures the substrate SUB using the line scan method, a first correcting may be performed. The first correcting is a process of checking and correcting the first camera CA1 for any misalignment in its screen using the first alignment key AK1 before moving in the second direction D2. Through the first correcting, the first camera CA1 may capture a first image of the substrate SUB without distortion.

For example, as illustrated in FIG. 4, the first-first camera CA1-1 may capture an image of the first-first alignment key AK1-1. In an example in which the first-first alignment key AK1-1 has a cross shape, the first-first camera CA1-1 may check whether a first axis and a second axis of the first-first alignment key AK1-1, which intersect each other, are parallel to the first direction D1 and the second direction D2 respectively. In some aspects, through the first correcting, the techniques described herein may check whether the first-first alignment key AK1-1 is positioned at a center of the screen of the first-first camera CA1-1.

The first correcting may be continued until the first axis and the second axis of the first-first alignment key AK1-1 become parallel to the first direction D1 and the second direction D2, respectively, in a screen of the first-first camera CA1-1. Moreover, the first correcting may proceed until the first-first alignment key AK1-1 is centered in a screen of the first-first camera CA1-1. Accordingly, when the first axis and the second axis of the first-first alignment key AK1-1 are parallel to the first direction D1 and the second direction D2 respectively, and the first-first alignment key AK1-1 is positioned at a center of the screen of the first-first camera CA1-1, the first camera CA1 may begin capturing the substrate SUB.

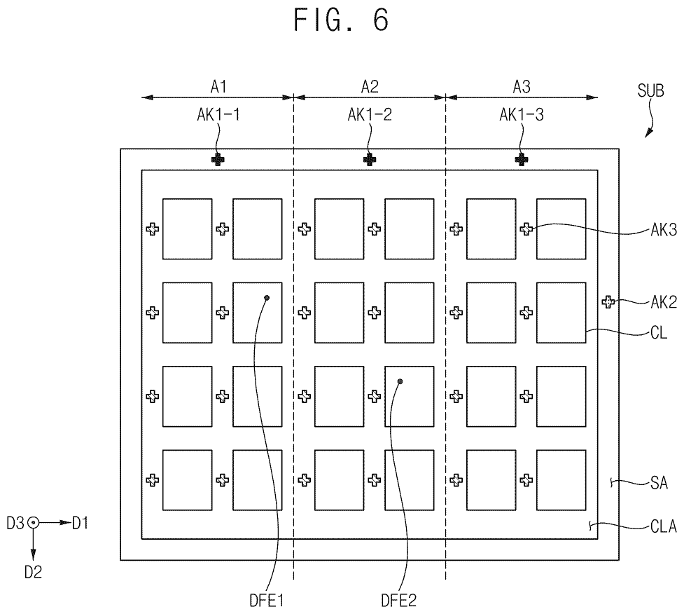

FIG. 6 is a plan view illustrating a first image captured of the substrate of FIG. 2.

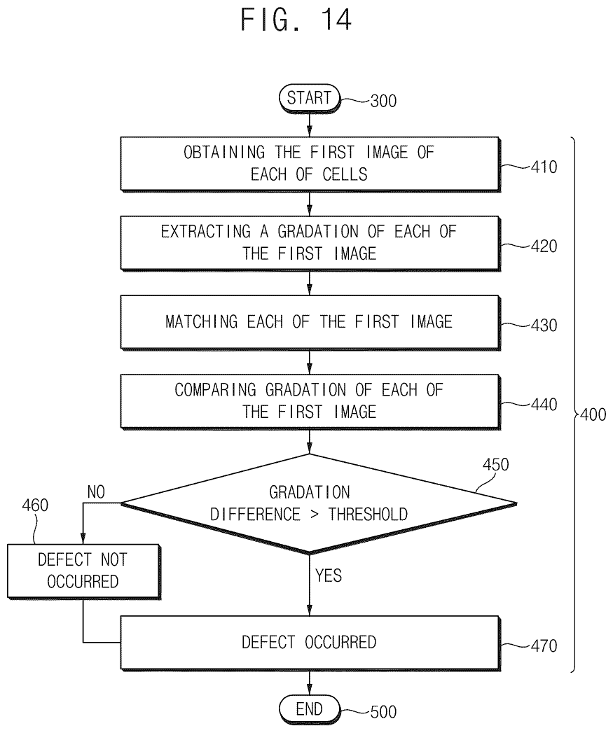

Referring to FIGS. 2, 3, and 6, after completing the first correcting, the first camera CA1 may capture an image of the substrate SUB to obtain the first image. The first image may be used to detect foreign substances DEF included in the substrate SUB. A method of detecting the foreign substances DEF in the first image using the first camera CA1 will be described later with reference to FIG. 14.

As illustrated in FIG. 6, each of the cells CL disposed on the substrate SUB may include foreign substances DEF. For example, one of the cells CL may include a first foreign substance DEF1, and another cell, spaced apart from the one of the cells CL, may include a second foreign substance DEF2. Although FIG. 6 illustrates a presence of the first foreign substance DEF1 and the second foreign substance DEF2, the embodiments of the disclosure are not necessarily limited thereto.

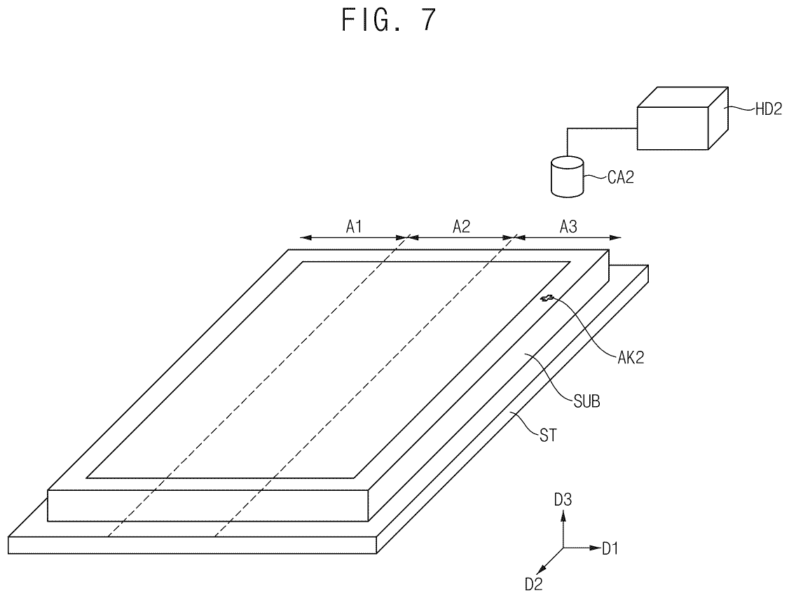

Coordinates of the foreign substances DEF included in the first image may be transmitted to the first processor (e.g., the first processor HD1 of FIG. 1), and the transmitted coordinates of the foreign substances DEF may be further transmitted to a second processor (e.g., a second processor HD2 of FIG. 7). The foreign substances DEF may be dust on the substrate SUB or areas affected by wiring short circuits, among others. However, the embodiments of the disclosure are not necessarily limited thereto.

FIG. 7 is a perspective view illustrating the second camera and the second alignment key.

Referring to FIGS. 6 and 7, the stage ST may move the substrate SUB to overlap with the second camera CA2 in a plan view. Specifically, the stage ST may move the substrate SUB such that the second alignment key AK2 of the substrate SUB overlaps with the second camera CA2 in a plan view. Accordingly, the second camera CA2 may capture an image of the second alignment key AK2.

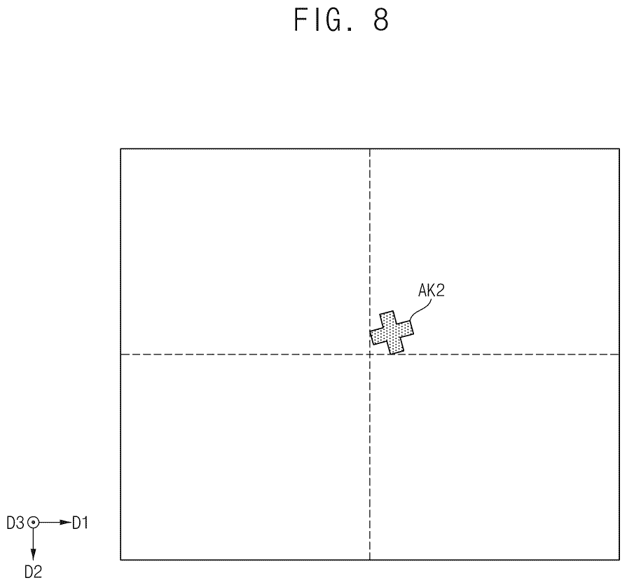

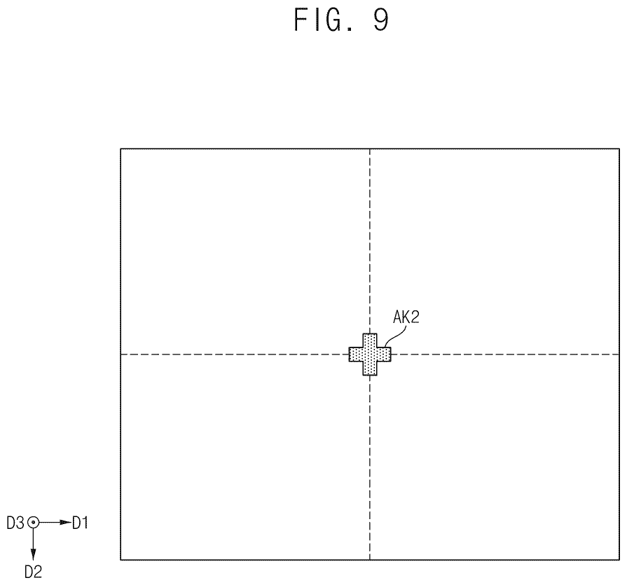

FIGS. 8 and 9 are plan views illustrating a second correcting of the second camera of FIG. 7. Specifically, FIGS. 8 and 9 illustrate a screen where the second camera CA2 captures the second alignment key AK2.

Referring to FIGS. 6, 7, 8, and 9, before capturing each of the cells CL including the foreign substance DEF in the substrate SUB, the second camera CA2 may perform a second correcting. That is, the second correcting is a process of checking and correcting any screen misalignment before the second camera CA2 moves to a position of the cells CL where foreign substances were detected.

A resolution of the second camera CA2 may be higher than a resolution of the first camera CA1. Accordingly, the second camera CA2 may more accurately determine a type of foreign substance DEF detected in the first image captured by the first camera CA1.

For example, the second camera CA2 may capture an image of the second alignment key AK2. In some aspects, the second alignment key AK2 may have a cross shape in a plan view, which may support checking whether a third axis and a fourth axis intersecting with the third axis of the second alignment key AK2 are parallel to the first direction D1 and the second direction D2 respectively in accordance with one or more embodiments of the present disclosure. In some aspects, through the second correcting, the techniques described herein may check whether the second alignment key AK2 is positioned at a center of the screen of the second camera CA2.

As illustrated in FIG. 7, when the second camera CA2 captures the second alignment key AK2, the third axis and the fourth axis of the second alignment key AK2 may not necessarily be parallel to the first direction D1 and the second direction D2. In correcting such misalignment of the second camera CA2, the second correcting may proceed until the third axis and the fourth axis of the second alignment key AK2 become parallel to the first direction D1 and the second direction D2 respectively. Furthermore, the second correcting may continue until the second alignment key AK2 is positioned at a center of the screen of the second camera CA2.

When the third axis and the fourth axis of the second alignment key AK2 are parallel to the first direction D1 and the second direction D2 respectively, and the second alignment key AK2 is positioned at a center of the screen of the second camera CA2, the second camera CA2 may begin capturing the substrate SUB.

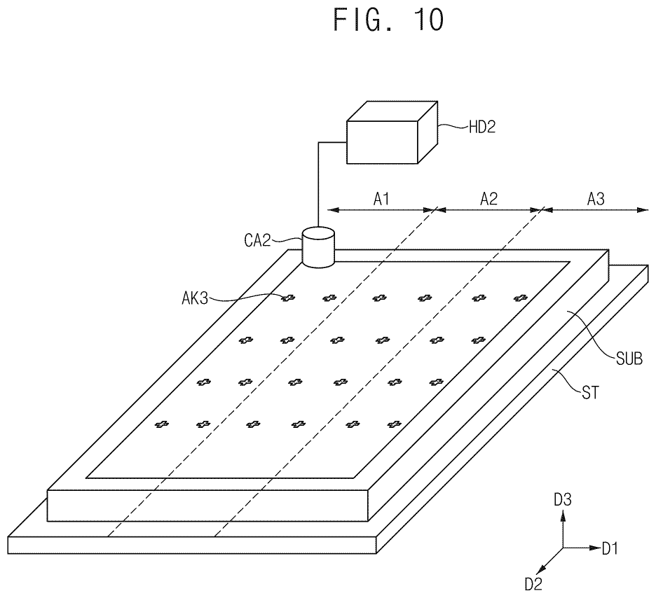

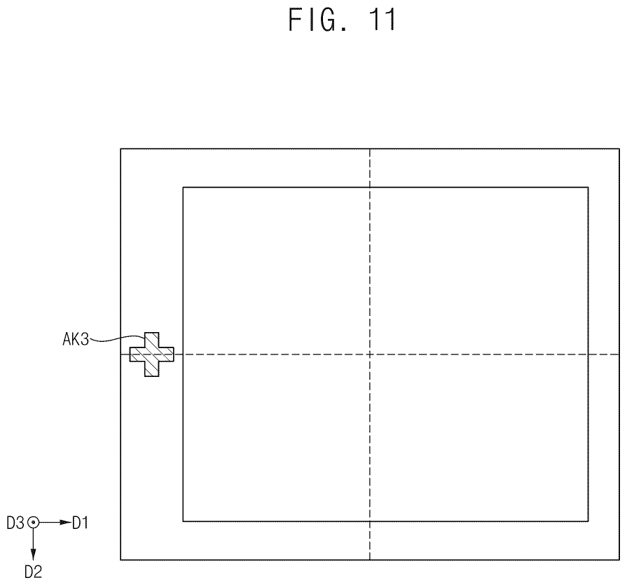

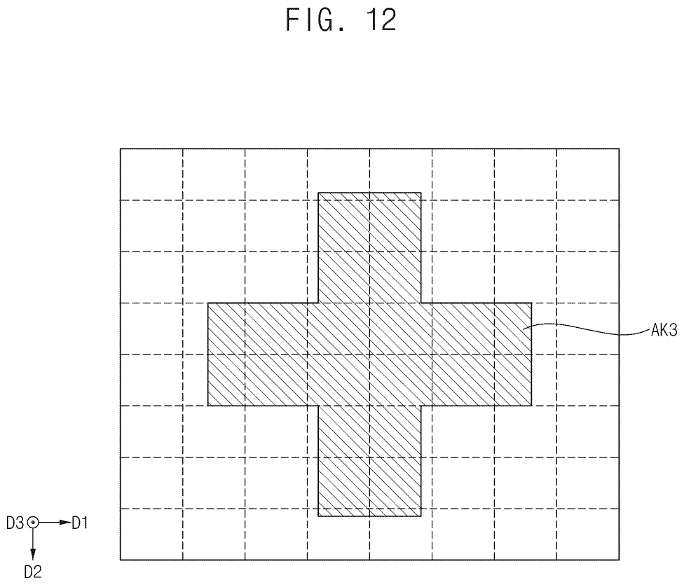

FIGS. 10, 11, and 12 are views illustrating a third correcting of the second camera of FIG. 10. Specifically, FIG. 10 is a perspective view illustrating the second camera CA2 capturing the substrate SUB. FIG. 11 is a plan view illustrating one of the cells CL and one of the third alignment keys AK3. FIG. 12 is a magnified plan view illustrating one of the third alignment keys AK3.

Before capturing each of the cells CL including the foreign substance DEF in the substrate SUB, the second camera CA2 may perform a third correcting. That is, the third correcting is a process of checking and correcting any screen misalignment before capturing each of the cells CL after the second camera CA2 moves to the position of the cells CL.

Referring to FIGS. 6 and 10, the stage ST may move the substrate SUB such that the second camera CA2 may capture an image of one of the cells CL including the foreign substance DEF. Specifically, the stage ST may move the substrate SUB such that one of the third alignment keys AK3, disposed on one side of one of the cells CL including the foreign substance DEF, overlaps with the second camera CA2 in a plan view.

Referring further to FIGS. 11 and 12, the second camera CA2 may capture an image of one of the third alignment keys AK3 disposed on one side of each of the cells CL. That is, as illustrated in FIG. 12, the second camera CA2 may capture an image of one of the third alignment keys AK3 such that the third alignment keys AK3 is positioned at a center of the screen of the second camera CA2.

In an embodiment, as illustrated in FIG. 11, each of the third alignment keys AK3 may be disposed at a center of one side of each of the cells CL. Specifically, each of the third alignment keys AK3 may be disposed along an imaginary line that crosses a center of each of the cells CL in parallel with the first direction D1. However, the embodiments of the disclosure are not necessarily limited thereto. Each of the third alignment keys AK3 may also be disposed along an imaginary line that crosses the center of each of the cells CL in parallel with the second direction D2.

The third correcting may be performed by comparing a pre-stored first gray level of the third alignment keys AK3 disposed on one side of the cells CL where the foreign substance DEF was detected with a second gray level obtained by capturing the third alignment keys AK3 using the second camera CA2.

Specifically, the pre-stored first gray level of one of the third alignment keys AK3 may refer to a gray level value obtained by capturing one of the third alignment keys AK3 with the second camera CA2 before detecting the foreign substance DEF. That is, the first gray levels of each of the third alignment keys AK3 may be stored as data. For example, as illustrated in FIG. 12, the first gray level may be an average gray level of 64 divided areas.

Similarly, with respect to 64 divided areas captured by the second camera CA2 and in which a third alignment key AK3 is included, the second gray level may be an average gray level among the 64 divided areas. In FIG. 12, a screen of the second camera CA2 is divided into 64 areas, however embodiments of the disclosure are not necessarily limited thereto. As the second camera CA2 is capable of capturing high-resolution images, areas may include millions or tens of millions of divisions (i.e., millions or tens of millions of areas).

Thereafter, the second gray level, which is a gray level of the third alignment keys AK3 disposed on one side of the cells CL where the foreign substance DEF was detected, may be obtained.

The first gray level and the second gray level may be normalized using the following equation:

$$Normalized Gray Scale ( f , g ) = \frac{( f ( x , y ) − \overline{f} ) ( g ( x , y ) − \overline{g} )}{\sum f ( x , y ) g ( x , y )} \qquad [ Formula 1 ]$$

Here, f(x, y) is a grayscale value for each area (e.g., 64 divided areas shown in FIG. 12) of the third alignment keys AK3, and f̅ is an average value of f(x, y). Similarly, g(x, y) is a grayscale value for each area of the third alignment keys AK3, and g is an average value of g(x, y).

The third correcting may proceed by normalizing the first grayscale and the second grayscale using Formula 1, until a value derived from Formula 1 is equal or more than 0.85. That is, when a value derived from Formula 1 is 0.85 or more, the second camera CA2 may determine that the misalignment has been corrected for capturing each of the cells CL. Consequently, by comparing grayscale levels of the third alignment keys AK3, the correction process may be carried out in a relatively simpler manner compared to directly correcting each image of the cells CL.

As a result, even when the substrate SUB is large (i.e., the substrate SUB has an area greater than a predetermined size), embodiments of the present disclosure support performing the first, second, and third correcting described herein in association with correcting misalignment in the first camera CA1 and the second camera CA2. Accordingly, a position of the foreign substance DEF may be accurately identified, which may support the second camera CA2 magnifying and precisely determining coordinates of the foreign substance DEF detected in the first image captured by the first camera CA1. Ultimately, the first camera CA1 and the second camera CA2 may analyze the foreign substance DEF to accurately identify and address issues in a manufacturing process of the substrate SUB.

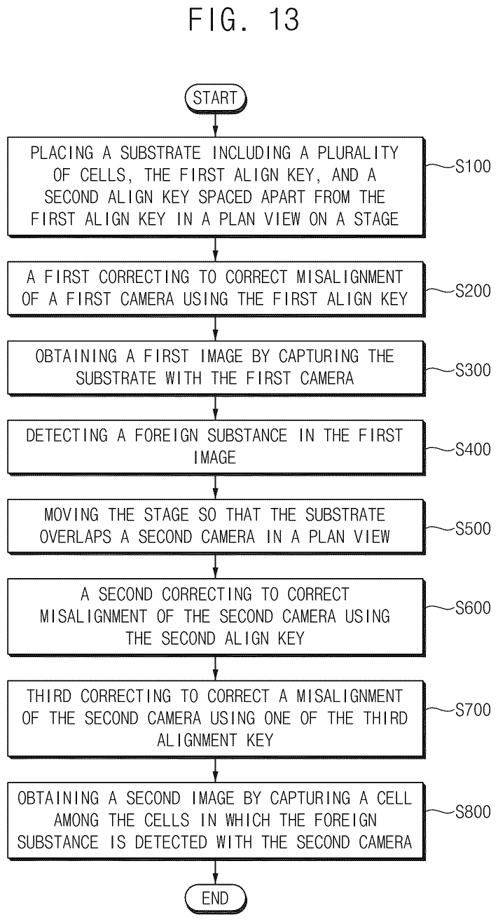

FIG. 13 is a flow-chart illustrating a method of inspecting the substrate according to an embodiment of the disclosure.

In the descriptions of the method and processes herein, the operations may be performed in a different order than the order shown and/or described, or the operations may be performed in different orders or at different times. Certain operations may also be left out of the flowcharts, one or more operations may be repeated, or other operations may be added. Descriptions that an element “may be disposed,” “may be formed,” “may be moved,” and the like include methods, processes, and techniques for disposing, forming, moving, and the like in accordance with example aspects described herein.

Referring to FIGS. 1 to 13, the method may include disposing (i.e., placing) the substrate SUB, including the first alignment key AK1 and the second alignment key AK2, on the stage ST (S100). Before capturing an image of the substrate SUB with the first camera CA1 (later described with reference to S300), the method may include performing the first correcting to verify that a screen of the first camera CA1 is not misaligned (S200).

Once the first correcting is completed, the method may include positioning the first alignment key AK1 at a center of the screen of the first camera CA1. In some aspects, the first axis and the second axis of the first alignment key AK1 may be parallel to the first direction D1 and the second direction D2 respectively. Then, the method may include capturing, using the first camera CA1, an image of the substrate SUB using the line scan method (S300) (i.e., obtaining a first image as described herein). As a position and misalignment of the first camera CA1 are corrected by the first correcting, coordinates of the foreign substance DEF within each of the cells CL may be obtained more accurately.

After capturing the substrate SUB using the first camera CA1, the method may include detecting, using the inspection device STD, the foreign substance DEF included in each of the cells CL disposed on the substrate SUB (S400). Then, the method may include transmitting coordinates of the foreign substance DEF by the inspection device STD to the second processor HD2. To identify the foreign substance DEF included in the cells CL, the method may include moving the stage ST in association with moving the substrate SUB, such that the substrate SUB overlaps with the second camera CA2 in a plan view (S500). The foreign substance DEF may be dust on the substrate SUB or a defect caused by a wiring short, among other issues. However, the embodiments of the disclosure are not necessarily limited thereto.

Before capturing images of each of the cells CL, the method may include performing a second correcting to verify that a screen of the second camera CA2 is not misaligned (S600). Once the second correcting is completed, the method may include positioning the second alignment key AK2 at a center of the screen of the second camera CA2. In some aspects, the third axis and the fourth axis of the second alignment key AK2 may be parallel to the first direction D1 and the second direction D2 respectively. Since position and misalignment of the second camera CA2 are corrected in the second correcting, the second camera CA2 may accurately move to coordinates of each of the cells CL.

Subsequently, the method may include capturing, using the second camera CA2, an image of one of the third alignment keys AK3 positioned on one side of the cells CL where the foreign substance DEF was detected. In an example in which the second camera CA2 moves from a position of the second alignment key AK2 to coordinates of one of the third alignment keys AK3, mechanical errors may cause the second camera CA2 from precisely aligning with the coordinates. To address this issue, the method may include performing the third correcting (S700). Finally, after completing the first correcting, the second correcting, and the third correcting, the method may include obtaining the second image by capturing an image of the foreign substance DEF included in each of the cells CL (S800). The method may accordingly determine a type of foreign substance DEF based on the steps described herein.

FIG. 14 is a flow-chart illustrating a step of detecting a foreign substance DEF (S400) of FIG. 13. Specifically, FIG. 14 is a flow-chart illustrating a process of extracting coordinates of the foreign substance DEF from the first image.

Referring to FIGS. 1 to 14, detecting the foreign substance DEF from the first image (S400) may include obtaining the first image, which represents an image of each of the cells CL, using the first camera CA1 (S410). That is, the first image may not be an image of an entire upper surface of the substrate SUB but rather an image of each individual cell CL included in the substrate SUB.

Then, the method may include extracting, by the gradation extraction portion SE included in the first processor HD1, a gradation of each first image (S420). After extracting a gradation of each first image, the method may include matching, by the alignment portion SU, each first image with each other (S430). Matching the first images may use each of the third alignment keys AK3 respectively disposed on one side of each of the cells CL. After matching the first images, the method may include comparing a gradation of each first image to determine a gradation difference (S440).

In response to determining the gradation difference exceeds a threshold value, the defect determination portion DJ may determine that the foreign substance DEF has occurred in the first image (S450, S470) (i.e., a foreign substance DEF is present or has been detected). In response to determining the gradation difference is below the threshold value, the defect determination portion DJ may determine that no foreign substance DEF has occurred (S460) (i.e., no foreign substance DEF is present or has been detected). In response to detecting the foreign substance DEF, the method may include obtaining and transmitting the coordinates of the defect DEF to the second processor HD2 connected to the second camera CA2.

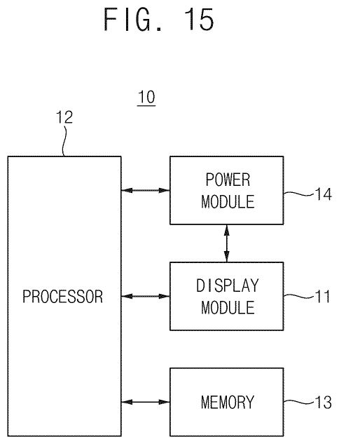

FIG. 15 is a block-diagram illustrating an electronic device according to an embodiment of the present disclosure.

Referring to FIGS. 2 and 15, the substrate SUB that has been inspected in the embodiments may be applied to various electronic devices 10. The electronic device 10 according to an embodiment may include the substrate SUB described herein and additional modules or devices with other functionalities.

The electronic device 10 may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), or a controller.

The memory 13 may store data or information for the operation of the processor 12 or the display module 11. In an example in which the processor 12 executes an application stored in the memory 13, video data signals and/or input control signals may be transmitted to the display module 11. The display module 11 may process the received signals and output visual information through a display screen.

The power module 14 may include power supply modules such as, for example, power adapters or battery devices and may convert the power supplied by the power supply module. Specifically, the power module 14 may include a power conversion module for generating power for the operation of the electronic device 10.

At least one of the components described herein of the electronic device 10 may be included within the display device according to the embodiments. In some aspects, some components functionally included in a single module may be partially included in the display device and partially provided separately. For example, the substrate SUB may include the display module 11, while the processor 12, the memory 13, and the power module 14 may be provided as part of another device within the electronic device 10 rather than the substrate SUB.

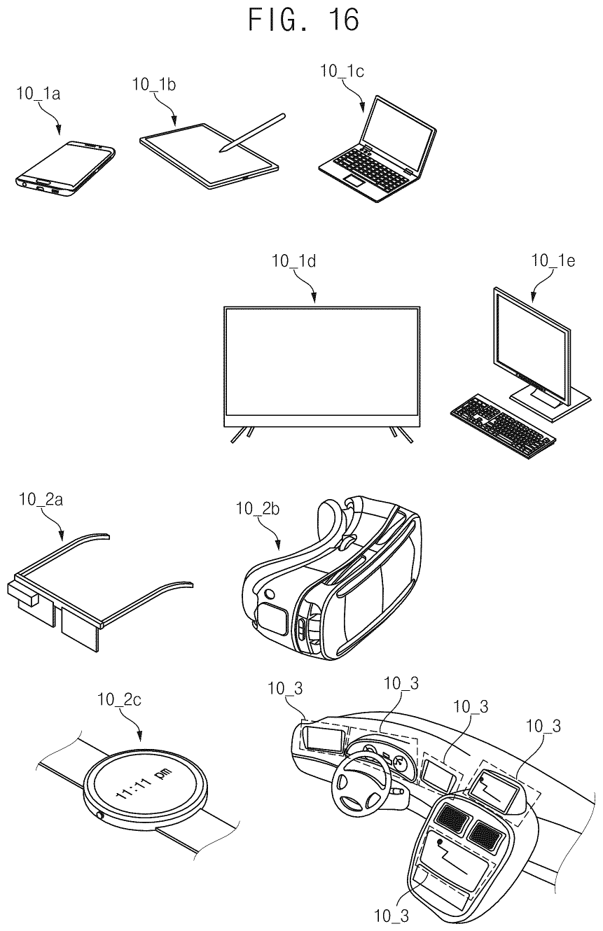

FIG. 16 is a schematic diagram of the electronic device according to various embodiments of FIG. 15.

Referring to FIGS. 15 and 16, various electronic devices 10 incorporating the substrate SUB according to the embodiments may include image display devices such as, for example, smartphones 10_1a, tablet PCs 10_1b, laptops 10_1c, TVs 10_1d, or desktop monitors 10_1e. In some aspects, wearable electronic devices such as, for example, smart glasses 10_2a, head-mounted displays 10_2b, or smartwatches 10_2c that include display modules may also be included. Automotive electronic devices, such as, for example, center information displays (CID), dashboard displays, or room mirror displays, incorporating display modules, may also be included.

However, these examples are illustrative, and the electronic device 10 according to the embodiments of the present disclosure is not necessarily limited thereto. For example, the electronic device 10 may be implemented as a mobile phone, videophone, smart pad, smartwatch, tablet PC, vehicle display, computer monitor, laptop, or head-mounted display device. In some aspects, the electronic device 10 may be a television, monitor, laptop computer, or tablet. Furthermore, the electronic device 10 may also be a vehicle.

While the disclosure has been particularly illustrated and described with reference to embodiments thereof, it will be understood by those of ordinary skill in the art that various changes in form and details may be made therein without departing from the spirit or scope of the disclosure as defined by the following claims.

What is claimed is:

1. A method of inspecting a substrate comprising:
placing a substrate comprising a plurality of cells, a first alignment key, and a second alignment key spaced apart from the first alignment key in a plan view on a stage;
performing a first correcting which corrects misalignment of a first camera using the first alignment key;
obtaining a first image by capturing an image of the substrate with the first camera;
detecting a foreign substance in the first image;
moving the stage such that the substrate overlaps a second camera in a plan view;
performing a second correcting which corrects misalignment of the second camera using the second alignment key; and
obtaining a second image by capturing, with the second camera, an image of a cell among the plurality of cells in which the foreign substance is detected.

2. The method of claim 1, wherein:
the substrate comprises a first area and a second area adjacent to the first area, and
the first alignment key comprises a first-first alignment key disposed in the first area and a first-second alignment key disposed in the second area.

3. The method of claim 2, wherein:
the first camera comprises a first-first camera and a first-second camera, and
capturing the substrate with the first camera comprises:
capturing the first area using the first-first camera, and
capturing the second area using the first-second camera.

4. The method of claim 1, wherein capturing the image of the substrate with the first camera is in a line scan manner.

5. The method of claim 1, wherein the substrate further comprises third alignment keys corresponding one-to-one with the plurality of cells.

6. The method of claim 5, each of the third alignment keys is disposed at a center of one side of a corresponding cell among the plurality of cells.

7. The method of claim 5, wherein each of the first alignment key, the second alignment key, and the third alignment keys has a cross shape in the plan view.

8. The method of claim 5, further comprising:
before obtaining the second image with the second camera, performing a third correcting which corrects a misalignment of the second camera using a third alignment key comprised among the third alignment keys, wherein the third alignment key corresponds to a cell in which the foreign substance is detected among the plurality of cells.

9. The method of claim 8, wherein the third correcting is performed using:
a pre-stored first grayscale of the third alignment key; and
a second grayscale of the third alignment key determined based on an image of the third alignment key as captured by the second camera.

10. The method of claim 9, wherein the third correcting is performed using Formula 1,
$$Normalized Gray Scale ( f , g ) = \frac{( f ( x , y ) − \overline{f} ) ( g ( x , y ) − \overline{g} )}{\sum f ( x , y ) g ( x , y )} \qquad ( 1 )$$
wherein:
f(x, y) is the second grayscale of the third alignment keys for each area,
f̅ is an average value of f(x, y),
g(x, y) is the pre-stored first grayscale of the third alignment keys for each area, and
g̅ is an average value of g(x, y).

11. The method of claim 10, wherein the third correcting is performed until a value of the Normalized Gray Scale(f, g) is equal to or more than 0.85.

12. The method of claim 5, wherein detecting the foreign substance in the first image comprises:
matching the first image of each of the plurality of cells with each other, and
determining that areas with a grayscale value difference greater than a preset threshold comprises a foreign substance.

13. The method of claim 12, wherein matching each first image of the cells comprises using the third alignment keys for the matching.

14. The method of claim 1, wherein the first correcting comprises verifying whether the first alignment key is positioned at a center of a screen of the first camera.

15. The method of claim 1, wherein the second correcting comprises verifying whether the second alignment key is positioned at a center of a screen of the second camera.

16. The method of claim 1, wherein a resolution of the second camera is higher than a resolution of the first camera.

17. A substrate comprising:
a cell area in which a plurality of cells is disposed; and
a peripheral area surrounding at least a portion of the cell area;
a first alignment key disposed in the peripheral area;
a second alignment key disposed in the peripheral area and spaced apart from the first alignment key in a plan view; and
third alignment keys disposed in the cell area, corresponding one-to-one with the plurality of cells, wherein each of the third alignment keys is disposed on one side of a corresponding cell among the plurality of cells.

18. The substrate of claim 17, wherein:
the substrate comprises a first area and a second area adjacent to the first area, and
the first alignment key comprises a first-first alignment key disposed in the first area and a first-second alignment key disposed in the second area.

19. The substrate of claim 17, wherein each of the first alignment key, the second alignment key, and the third alignment keys has a cross shape in the plan view.

20. An electronic device comprising:
a display device; and
a processor configured to drive the display device,
wherein the display device is inspected by a method of inspecting a substrate comprising:
placing a substrate comprising a plurality of cells, a first alignment key, and a second alignment key spaced apart from the first alignment key in a plan view on a stage;
performing a first correcting which corrects misalignment of a first camera using the first alignment key;
obtaining a first image by capturing an image of the substrate with the first camera;
detecting a foreign substance in the first image;
moving the stage such that the substrate overlaps a second camera in a plan view;
performing a second correcting which corrects misalignment of the second camera using the second alignment key; and
obtaining a second image by capturing, with the second camera, an image of a cell among the plurality of cells in which the foreign substance is detected.
